(19) United States
(12) Patent Application Publication
(10) Pub. No.: US 2024/0144839 A1
(43) Pub. Date: May 2, 2024

(54) SYSTEM AND METHOD FOR SIMULATING A STORAGE SYSTEM IN A VIRTUAL ENVIRONMENT

(71) Applicant: Dell Products, L.P., Round Rock, TX (US)

(72) Inventors: Alex Kulakovsky, Raanana (IL); Osnat Sasha, Holon (IL); Yuval Harduf, Yahud (IL)

(21) Appl. No.: 17/973,606

(22) Filed: Oct. 26, 2022

(51) Int. Cl. G09B 9/00

(52) U.S. Cl. CPC G09B 9/00

(57) ABSTRACT

A method, computer program product, and computing system for receiving an action alert from a virtual reality system concerning a virtual reality representation of a storage system. The action alert is translated into a storage system simulator event using a virtual reality logic engine. A storage system simulation corresponding to the virtual reality representation of the storage system is updated using the storage system simulator event.

### BACKGROUND

Storing and safeguarding electronic content may be beneficial in modern business and elsewhere. Accordingly, various methodologies may be employed to protect and distribute such electronic content.

For example, service provider and information technology (IT) technician human errors are considered a major problem in data centers housing storage systems. According to a recent survey, human errors account for approximately 70% of data center problems, leading to system downtime and costly security breaches. For storage systems, such errors might lead to Data Unavailability (DU) or even Data Loss (DL). This results in: a negative impact on customer business and customer satisfaction with the product; a potential increase in the chance of a customer switching to a competitor; and bad publicity. It might also result in repeated technician visits to fix the issues and high costs associated with it.

Reasons for technician errors might vary. For example, a technician may not understand and may fail to follow a procedure correctly. The technician may lack practice with specific product or may lack understanding of the equipment/product. The multiplicity of very complex products and wiring schemes may lead to confusion. A technician may not embed “lessons learned” from field cases or the technician may not have practiced certain procedures enough, especially before visiting a customer site.

Many of these can be addressed by better and more up-to-date training and practice before reaching the field. However, this is difficult because such training: 1) requires access to the lab and availability of the specific physical equipment; 2) requires having access to latest training materials for all products and the inefficiency learning from recorded sessions; and 3) requires the technician to be up-to-date with the latest “lessons learned”.

### SUMMARY OF DISCLOSURE

In one example implementation, a computer-implemented method executed on a computing device may include, but is not limited to, receiving an action alert from a virtual reality system concerning a virtual reality representation of a storage system. The action alert is translated into a storage system simulator event using a virtual reality logic engine. A storage system simulation corresponding to the virtual reality representation of the storage system is updated using the storage system simulator event.

One or more of the following example features may be included. Updating the storage system simulation includes providing the storage system simulator event to the storage system simulation using an application programming interface (API). Updating the storage system simulation includes updating a storage system simulation state. Updating the storage system simulation includes updating a user interface state for a user interface of the virtual reality representation of the storage system. The virtual reality representation of the storage system on the virtual reality system is updated. Updating the virtual reality representation of the storage system on the virtual reality system includes updating the user interface of the virtual reality representation of the storage system. The virtual reality representation of the storage system and the storage system simulation are associated with a training program for a storage system.

In another example implementation, a computer program product resides on a computer readable medium that has a plurality of instructions stored on it. When executed by a processor, the instructions cause the processor to perform operations that may include, but are not limited to, receiving an action alert from a virtual reality system concerning a virtual reality representation of a storage system. The action alert is translated into a storage system simulator event using a virtual reality logic engine. A storage system simulation corresponding to the virtual reality representation of the storage system is updated using the storage system simulator event.

One or more of the following example features may be included. Updating the storage system simulation includes providing the storage system simulator event to the storage system simulation using an application programming interface (API). Updating the storage system simulation includes updating a storage system simulation state. Updating the storage system simulation includes updating a user interface state for a user interface of the virtual reality representation of the storage system. The virtual reality representation of the storage system on the virtual reality system is updated. Updating the virtual reality representation of the storage system on the virtual reality system includes updating the user interface of the virtual reality representation of the storage system. The virtual reality representation of the storage system and the storage system simulation are associated with a training program for a storage system.

In another example implementation, a computing system includes at least one processor and at least one memory architecture coupled with the at least one processor, wherein the at least one processor configured to receive an action alert from a virtual reality system concerning a virtual reality representation of a storage system. The action alert is translated into a storage system simulator event using a virtual reality logic engine. A storage system simulation corresponding to the virtual reality representation of the storage system is updated using the storage system simulator event.

One or more of the following example features may be included. Updating the storage system simulation includes providing the storage system simulator event to the storage system simulation using an application programming interface (API). Updating the storage system simulation includes updating a storage system simulation state. Updating the storage system simulation includes updating a user interface state for a user interface of the virtual reality representation of the storage system. The virtual reality representation of the storage system on the virtual reality system is updated. Updating the virtual reality representation of the storage system on the virtual reality system includes updating the user interface of the virtual reality representation of the storage system. The virtual reality representation of the storage system and the storage system simulation are associated with a training program for a storage system.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF THE DRAWINGS

FIG. 1 is an example diagrammatic view of a storage system and a simulation process coupled to a distributed computing network according to one or more example implementations of the disclosure;

FIG. 2 is an example diagrammatic view of the storage system of FIG. 1 according to one or more example implementations of the disclosure;

FIG. 3 is an example flowchart of simulation process according to one or more example implementations of the disclosure;

FIG. 4 is an example diagrammatic view of a virtual reality system according to one or more example implementations of the disclosure;

FIG. 5 is an example diagrammatic view of a virtual reality display engine according to one or more example implementations of the disclosure;

FIG. 6 is an example diagrammatic view of a virtual reality environment and a storage system simulator according to one or more example implementations of the disclosure; and

FIGS. 7-16 are example diagrammatic views of various virtual reality representations of a storage system according to example implementations of the disclosure.

Like reference symbols in the various drawings indicate like elements.

### DETAILED DESCRIPTION

### System Overview:

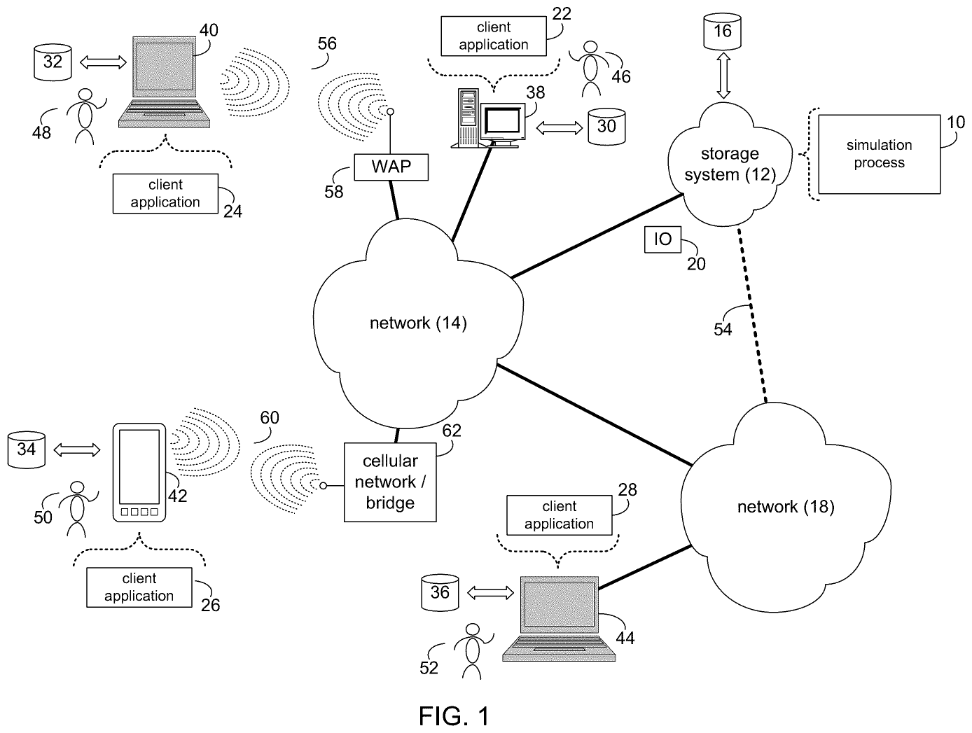

Referring to FIG. 1, there is shown simulation process 10 that may reside on and may be executed by storage system 12, which may be connected to network 14 (e.g., the Internet or a local area network). Examples of storage system 12 may include, but are not limited to: a Network Attached Storage (NAS) system, a Storage Area Network (SAN), a personal computer with a memory system, a server computer with a memory system, and a cloud-based device with a memory system.

As is known in the art, a SAN may include one or more of a personal computer, a server computer, a series of server computers, a mini computer, a mainframe computer, a RAID device and a NAS system. The various components of storage system 12 may execute one or more operating systems, examples of which may include but are not limited to: Microsoft® Windows®; Mac® OS X®; Red Hat® Linux®, Windows® Mobile, Chrome OS, Blackberry OS, Fire OS, or a custom operating system. (Microsoft and Windows are registered trademarks of Microsoft Corporation in the United States, other countries or both; Mac and OS X are registered trademarks of Apple Inc. in the United States, other countries or both; Red Hat is a registered trademark of Red Hat Corporation in the United States, other countries or both; and Linux is a registered trademark of Linus Torvalds in the United States, other countries or both).

The instruction sets and subroutines of simulation process 10, which may be stored on storage device 16 included within storage system 12, may be executed by one or more processors (not shown) and one or more memory architectures (not shown) included within storage system 12. Storage device 16 may include but is not limited to: a hard disk drive; a tape drive; an optical drive; a RAID device; a random access memory (RAM); a read-only memory (ROM); and all forms of flash memory storage devices. Additionally/alternatively, some portions of the instruction sets and subroutines of simulation process 10 may be stored on storage devices (and/or executed by processors and memory architectures) that are external to storage system 12.

Network 14 may be connected to one or more secondary networks (e.g., network 18), examples of which may include but are not limited to: a local area network; a wide area network; or an intranet, for example.

Various IO requests (e.g. IO request 20) may be sent from client applications 22, 24, 26, 28 to storage system 12. Examples of IO request 20 may include but are not limited to data write requests (e.g., a request that content be written to storage system 12) and data read requests (e.g., a request that content be read from storage system 12).

The instruction sets and subroutines of client applications 22, 24, 26, 28, which may be stored on storage devices 30, 32, 34, 36 (respectively) coupled to client electronic devices 38, 40, 42, 44 (respectively), may be executed by one or more processors (not shown) and one or more memory architectures (not shown) incorporated into client electronic devices 38, 40, 42, 44 (respectively). Storage devices 30, 32, 34, 36 may include but are not limited to: hard disk drives; tape drives; optical drives; RAID devices; random access memories (RAM); read-only memories (ROM), and all forms of flash memory storage devices. Examples of client electronic devices 38, 40, 42, 44 may include, but are not limited to, personal computer 38, laptop computer 40, smartphone 42, notebook computer 44, a server (not shown), a data-enabled, cellular telephone (not shown), and a dedicated network device (not shown).

Users 46, 48, 50, 52 may access storage system 12 directly through network 14 or through secondary network 18. Further, storage system 12 may be connected to network 14 through secondary network 18, as illustrated with link line 54.

The various client electronic devices may be directly or indirectly coupled to network 14 (or network 18). For example, personal computer 38 is shown directly coupled to network 14 via a hardwired network connection. Further, notebook computer 44 is shown directly coupled to network 18 via a hardwired network connection. Laptop computer 40 is shown wirelessly coupled to network 14 via wireless communication channel 56 established between laptop computer 40 and wireless access point (e.g., WAP) 58, which is shown directly coupled to network 14. WAP 58 may be, for example, an IEEE 802.11a, 802.11b, 802.11g, 802.11n, Wi-Fi, and/or Bluetooth device that is capable of establishing wireless communication channel 56 between laptop computer 40 and WAP 58. Smartphone 42 is shown wirelessly coupled to network 14 via wireless communication channel 60 established between smartphone 42 and cellular network/bridge 62, which is shown directly coupled to network 14.

Client electronic devices 38, 40, 42, 44 may each execute an operating system, examples of which may include but are not limited to Microsoft® Windows®; Mac® OS X®; Red Hat® Linux®, Windows® Mobile, Chrome OS, Blackberry OS, Fire OS, or a custom operating system. (Microsoft and Windows are registered trademarks of Microsoft Corporation in the United States, other countries or both; Mac and OS X are registered trademarks of Apple Inc. in the United States, other countries or both; Red Hat is a registered trademark of Red Hat Corporation in the United States, other countries or both; and Linux is a registered trademark of Linus Torvalds in the United States, other countries or both).

In some implementations, as will be discussed below in greater detail, a simulation process, such as simulation process 10 of FIG. 1, may include but is not limited to, receiving an action alert from a virtual reality system concerning a virtual reality representation of a storage system. The action alert is translated into a storage system simulator event using a virtual reality logic engine. A storage system simulation corresponding to the virtual reality representation of the storage system is updated using the storage system simulator event.

For example purposes only, storage system 12 will be described as being a network-based storage system that includes a plurality of electro-mechanical backend storage devices. However, this is for example purposes only and is not intended to be a limitation of this disclosure, as other configurations are possible and are considered to be within the scope of this disclosure.

### The Storage System:

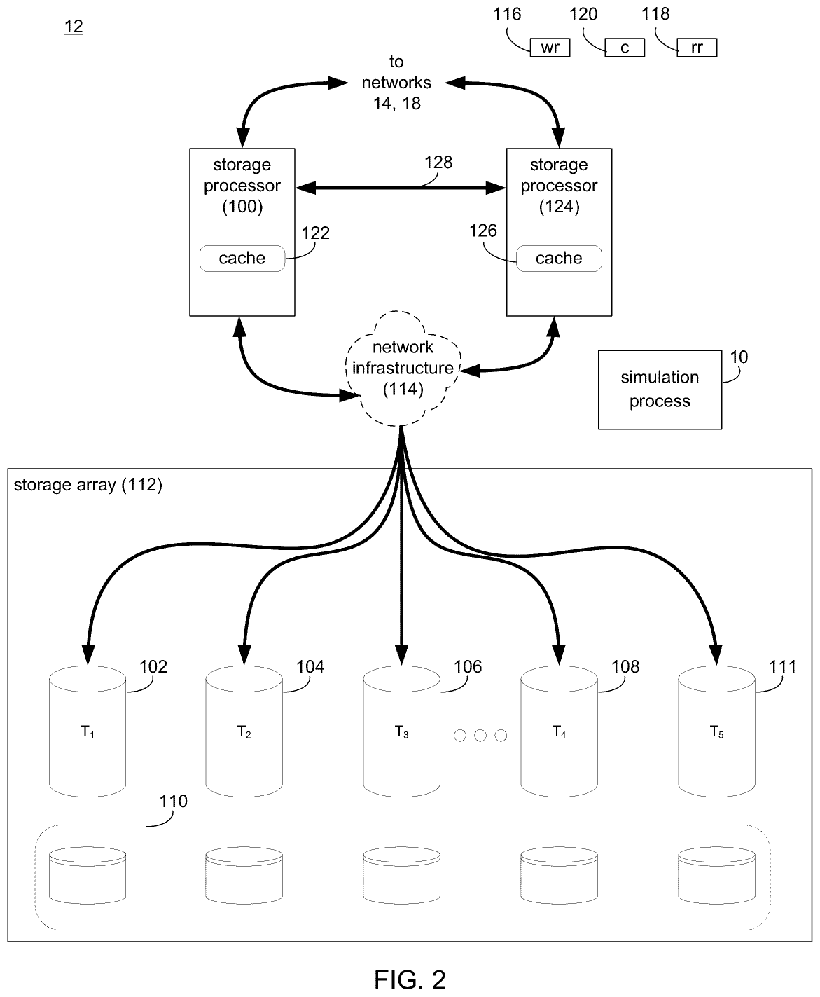

Referring also to FIG. 2, storage system 12 may include storage processor 100 and a plurality of storage targets T 1-n (e.g., storage targets 102, 104, 106, 108). Storage targets 102, 104, 106, 108 may be configured to provide various levels of performance and/or high availability. For example, one or more of storage targets 102, 104, 106, 108 may be configured as a RAID 0 array, in which data is striped across storage devices (e.g., storage devices 110) used to create the storage targets. By striping data across a plurality of storage targets, improved performance may be realized. However, RAID 0 arrays do not provide a level of high availability. Accordingly, one or more of storage targets 102, 104, 106, 108 may be configured as a RAID 1 array, in which data is mirrored between storage devices used to create the storage targets. By mirroring data between storage devices, a level of high availability is achieved as multiple copies of the data are stored within storage system 12.

While storage targets 102, 104, 106, 108 are discussed above as being configured in a RAID 0 or RAID 1 array, this is for example purposes only and is not intended to be a limitation of this disclosure, as other configurations are possible. For example, storage targets 102, 104, 106, 108 may be configured as a RAID 3, RAID 4, RAID 5 or RAID 6 array.

While in this particular example, storage system 12 is shown to include four storage targets (e.g. storage targets 102, 104, 106, 108), this is for example purposes only and is not intended to be a limitation of this disclosure. Specifically, the actual number of storage targets may be increased or decreased depending upon e.g., the level of redundancy/performance/capacity required.

Storage system 12 may also include one or more coded targets 111. As is known in the art, a coded target may be used to store coded data that may allow for the regeneration of data lost/corrupted on one or more of storage targets 102, 104, 106, 108. An example of such a coded target may include but is not limited to a hard disk drive that is used to store parity data within a RAID array.

While in this particular example, storage system 12 is shown to include one coded target (e.g., coded target 111), this is for example purposes only and is not intended to be a limitation of this disclosure. Specifically, the actual number of coded targets may be increased or decreased depending upon e.g. the level of redundancy/performance/capacity required.

Storage targets 102, 104, 106, 108 and coded target 111 may be created as volumes using one or more electro-mechanical hard disk drives and/or solid-state/flash devices (e.g., storage devices 110), wherein a combination of storage targets 102, 104, 106, 108 and coded target 111 and processing/control systems (not shown) may form data array 112.

The manner in which storage system 12 is implemented may vary depending upon e.g. the level of redundancy/performance/capacity required. For example, storage system 12 may be a RAID device in which storage processor 100 is a RAID controller card and storage targets 102, 104, 106, 108 and/or coded target 111 are individual “hot-swappable” hard disk drives. Another example of such a RAID device may include but is not limited to an NAS device. Alternatively, storage system 12 may be configured as a SAN, in which storage processor 100 may be e.g., a server computer and each of storage targets 102, 104, 106, 108 and/or coded target 111 may be a RAID device and/or computer-based hard disk drives. Further still, one or more of storage targets 102, 104, 106, 108 and/or coded target 111 may be a SAN.

In the event that storage system 12 is configured as a SAN, the various components of storage system 12 (e.g. storage processor 100, storage targets 102, 104, 106, 108, and coded target 111) may be coupled using network infrastructure 114, examples of which may include but are not limited to an Ethernet (e.g., Layer 2 or Layer 3) network, a fiber channel network, an InfiniBand network, or any other circuit switched/packet switched network.

Storage system 12 may execute all or a portion of simulation process 10. The instruction sets and subroutines of simulation process 10, which may be stored on a storage device (e.g., storage device 16) coupled to storage processor 100, may be executed by one or more processors (not shown) and one or more memory architectures (not shown) included within storage processor 100. Storage device 16 may include but is not limited to: a hard disk drive; a tape drive; an optical drive; a RAID device; a random access memory (RAM); a read-only memory (ROM); and all forms of flash memory storage devices. As discussed above, some portions of the instruction sets and subroutines of simulation process 10 may be stored on storage devices (and/or executed by processors and memory architectures) that are external to storage system 12.

As discussed above, various IO requests (e.g. IO request 20) may be generated. For example, these IO requests may be sent from client applications 22, 24, 26, 28 to storage system 12. Additionally/alternatively and when storage processor 100 is configured as an application server, these IO requests may be internally generated within storage processor 100. Examples of IO request 20 may include but are not limited to data write request 116 (e.g., a request that content 118 be written to storage system 12) and data read request 120 (i.e. a request that content 118 be read from storage system 12).

During operation of storage processor 100, content 118 to be written to storage system 12 may be processed by storage processor 100. Additionally/alternatively and when storage processor 100 is configured as an application server, content 118 to be written to storage system 12 may be internally generated by storage processor 100.

Storage processor 100 may include frontend cache memory system 122. Examples of frontend cache memory system 122 may include but are not limited to a volatile, solid-state, cache memory system (e.g., a dynamic RAM cache memory system) and/or a non-volatile, solid-state, cache memory system (e.g., a flash-based, cache memory system).

Storage processor 100 may initially store content 118 within frontend cache memory system 122. Depending upon the manner in which frontend cache memory system 122 is configured, storage processor 100 may immediately write content 118 to data array 112 (if frontend cache memory system 122 is configured as a write-through cache) or may subsequently write content 118 to data array 112 (if frontend cache memory system 122 is configured as a write-back cache).

As discussed above, the instruction sets and subroutines of simulation process 10, which may be stored on storage device 16 included within storage system 12, may be executed by one or more processors (not shown) and one or more memory architectures (not shown) included within storage system 12. Accordingly, in addition to being executed on storage processor 100, some or all of the instruction sets and subroutines of simulation process 10 may be executed by one or more processors (not shown) and one or more memory architectures (not shown) included within data array 112.

Further and as discussed above, during the operation of data array 112, content (e.g., content 118) to be written to data array 112 may be received from storage processor 100 and initially stored within backend cache memory system 124 prior to being stored on e.g. one or more of storage targets 102, 104, 106, 108, 111. Accordingly, during use of data array 112, backend cache memory system 124 may be populated (e.g., warmed) and, therefore, subsequent read requests may be satisfied by backend cache memory system 124 (e.g., if the content requested in the read request is present within backend cache memory system 124), thus avoiding the need to obtain the content from storage targets 102, 104, 106, 108, 111 (which would typically be slower).

In some implementations, storage system 12 may include multi-node active/active storage clusters configured to provide high availability to a user. As is known in the art, the term “high availability” may generally refer to systems or components that are durable and likely to operate continuously without failure for a long time. For example, an active/active storage cluster may be made up of at least two nodes (e.g., storage processors 100, 124), both actively running the same kind of service(s) simultaneously. One purpose of an active-active cluster may be to achieve load balancing. Load balancing may distribute workloads across all nodes in order to prevent any single node from getting overloaded. Because there are more nodes available to serve, there will also be a marked improvement in throughput and response times. Another purpose of an active-active cluster may be to provide at least one active node in the event that one of the nodes in the active-active cluster fails.

In some implementations, storage processor 124 may function like storage processor 100. For example, during operation of storage processor 124, content 118 to be written to storage system 12 may be processed by storage processor 124. Additionally/alternatively and when storage processor 124 is configured as an application server, content 118 to be written to storage system 12 may be internally generated by storage processor 124.

Storage processor 124 may include frontend cache memory system 126. Examples of frontend cache memory system 126 may include but are not limited to a volatile, solid-state, cache memory system (e.g., a dynamic RAM cache memory system) and/or a non-volatile, solid-state, cache memory system (e.g., a flash-based, cache memory system).

Storage processor 124 may initially store content 118 within frontend cache memory system 124. Depending upon the manner in which frontend cache memory system 126 is configured, storage processor 124 may immediately write content 118 to data array 112 (if frontend cache memory system 126 is configured as a write-through cache) or may subsequently write content 118 to data array 112 (if frontend cache memory system 126 is configured as a write-back cache).

In some implementations, the instruction sets and subroutines of simulation process 10, which may be stored on storage device 16 included within storage system 12, may be executed by one or more processors (not shown) and one or more memory architectures (not shown) included within storage system 12. Accordingly, in addition to being executed on storage processor 124, some or all of the instruction sets and subroutines of simulation process 10 may be executed by one or more processors (not shown) and one or more memory architectures (not shown) included within data array 112.

Further and as discussed above, during the operation of data array 112, content (e.g., content 118) to be written to data array 112 may be received from storage processor 124 and initially stored within backend cache memory system 124 prior to being stored on e.g. one or more of storage targets 102, 104, 106, 108, 111. Accordingly, during use of data array 112, backend cache memory system 124 may be populated (e.g., warmed) and, therefore, subsequent read requests may be satisfied by backend cache memory system 124 (e.g., if the content requested in the read request is present within backend cache memory system 124), thus avoiding the need to obtain the content from storage targets 102, 104, 106, 108, 111 (which would typically be slower).

As discussed above, storage processor 100 and storage processor 124 may be configured in an active/active configuration where processing of data by one storage processor may be synchronized to the other storage processor. For example, data may be synchronized between each storage processor via a separate link or connection (e.g., connection 128).

### The Simulation Process:

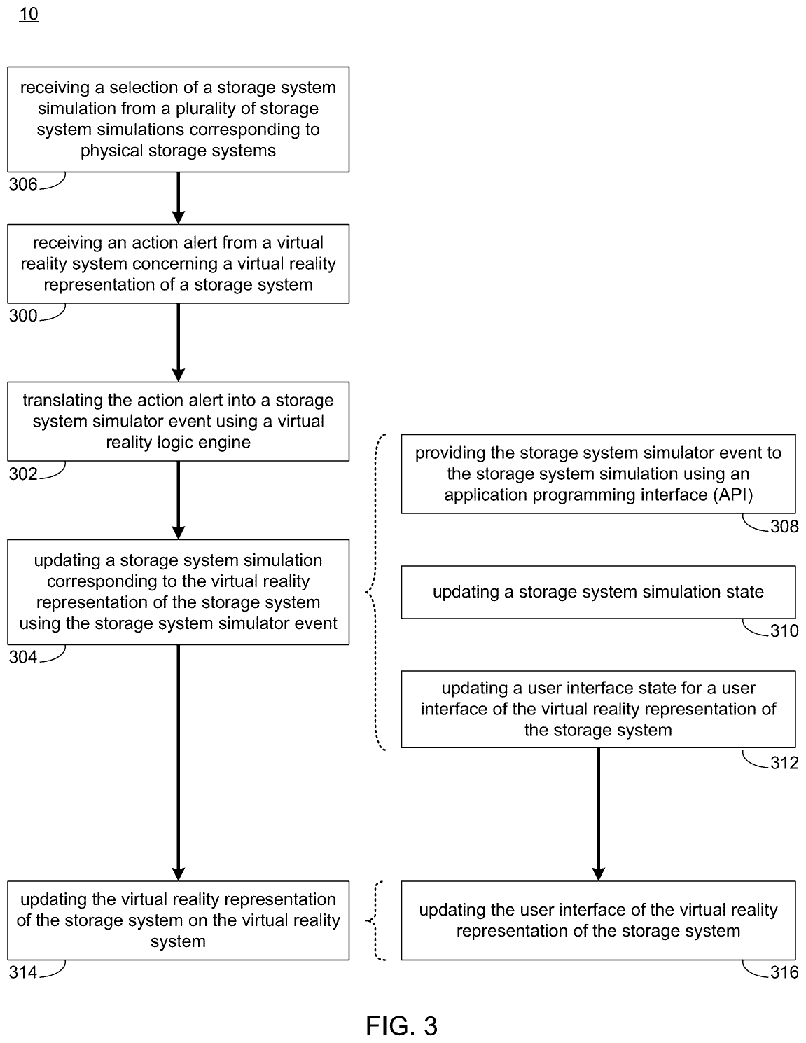

Referring also to the examples of FIGS. 3-16 and in some implementations, simulation process 10 may receive 300 an action alert from a virtual reality system concerning a virtual reality representation of a storage system. The action alert is translated 302 into a storage system simulator event using a virtual reality logic engine. A storage system simulation corresponding to the virtual reality representation of the storage system is updated 304 using the storage system simulator event.

As will be discussed in greater detail below, implementations of the present disclosure may allow for the integration of a simulated storage system with a virtual reality system. For example, implementations of the present disclosure provide for effective interfacing between virtual reality systems and storage system simulators. This allows for the imitation of real storage system behavior by updating graphical user interfaces, control LEDs, alerts, etc. all within the virtual reality environment using storage system simulation information. In this manner, limitations in the programming of virtual reality systems to account for complex storage system simulations are resolved by interfacing directly with a storage system simulator. The present disclosure also infers simple interoperability between the components allowing the movement to a different simulator version (e.g., following a new product release) with minimal-to-no adaptations to the virtual reality system. This enables much simpler sustainability and reduces development costs with introduction of new releases.

Training using virtual reality can overcome the obstacles posed by the conventional methods. Simulations remove the requirement to physically access a product to gain hands-on understanding of its workings. Further, simulations remove the requirement that the user have physical access to the product, which may in limited supply or otherwise not easily available. Additionally, by simulating the environment in which the user would install, repair, or maintain a product, the user can practice performing the tasks before they are required. Gaining familiarity with products and the steps needed to address their issues increases the user's confidence in their ability to remedy problems when they arise. In fact, even when a problem surfaces, through the virtual simulations, the user can practice remedying the issue before attempting to work on the product itself. Thus, a computing device that uses virtual reality to train a user to address issues for a product can increase the likelihood of the user successfully installing, repairing, and maintaining the product, and thus improve the user's satisfaction with the product. Additionally, the present computing device can reduce the duration of the user's service visits to customer sites for repairing physical products, thereby reducing costs for the customer and for the user's employer.

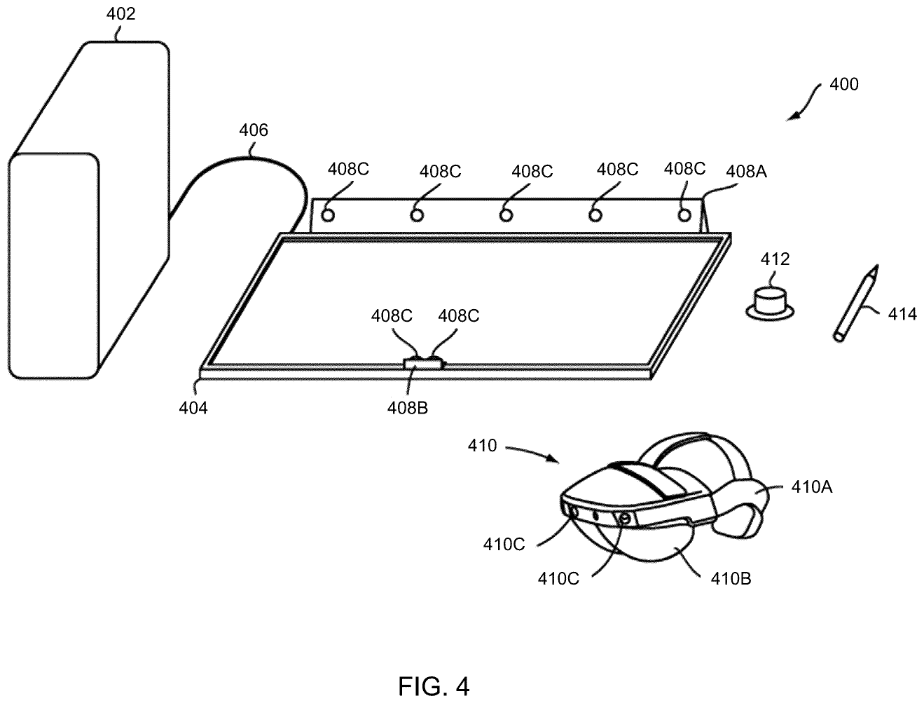

Referring now to FIG. 4, an embodiment of a virtual reality system (e.g., virtual reality system 400) is illustrated. In the illustrated embodiment, the virtual reality system 400 includes a computing device (e.g., computing device 402) that may be computing device 12 with reference to FIG. 1. One of skill in the art in possession of the present disclosure will recognize that while the computing device 402 is illustrated as a desktop computing device, other types of computing devices (e.g., laptop/notebook computing devices and/or other mobile computing devices, computing devices integrated into other components of virtual reality system 400, and/or other types of computing devices) will fall within the scope of the present disclosure as well. As discussed in further detail below, computing device 402 may be coupled to other components of virtual reality system 400 via wired and/or wireless couplings.

For example, virtual reality system 400 of the illustrated embodiment includes a physical display device (e.g., physical display device 404) that is connected to computing device 402 by a wired connection (e.g., wired connection 406), although wireless connections between computing device 402 and physical display device 404 (or integration of at least some of the computing device functionality discussed below in physical display device 404) will fall within the scope of the present disclosure as well. Physical display device 404 includes a display screen (e.g., display screen 404A) that, in the embodiments illustrated and discussed below, is provided in a substantially horizontal orientation relative to a user of virtual reality system 400, as well as substantially parallel to the support surface upon which it is located (e.g., a working surface of a desk). For example, one of skill in the art in possession of the present disclosure will recognize that display screens have been traditionally provided in substantially vertical orientations relative to users, as well as substantially perpendicularly to their support surfaces (e.g., the working surface of the desk discussed above), and that display screen 404A of physical display device 404 is described below as provided in a substantially horizontal orientation that is rotated substantially ninety degrees from those substantially vertical orientations. For example, physical display device 404 may be provided as part of a “smart desk” that provides a horizontally oriented, touch-input display device (which may be utilized by itself or in conjunction with a vertically oriented display device), although other horizontally oriented display screens will fall within the scope of the present disclosure as well. Furthermore, the provisioning of physical display device 404 and display screen 404A in other orientations (e.g., the vertical orientation discussed above) will fall within the scope of the present disclosure as well.

In the illustrated embodiment, a user tracking subsystem (e.g., user tracking subsystems 408A and 408B) is integrated with physical display device 404, although a user tracking subsystem that is separate from physical display device 404 (and separately coupled to computing device 402 via a wired or wireless connection) will fall within the scope of the present disclosure as well. As such, in some embodiments user tracking subsystem 408A and 408B may include at least some of the computing device functionality described below for the physical display device 404. User tracking subsystem 408A and 408B may include a plurality of user tracking devices (e.g., user tracking device 408C) that may be provided by infrared (IR) sensors, IR sensor arrays (e.g., “IR castors”), three-dimensional cameras (e.g., if the processing system in the computing system has sufficient processing capabilities), and/or a variety of other user tracking devices that would be apparent to one of skill in the art in possession of the present disclosure. While virtual reality system 400 is illustrated with user tracking subsystem 408A positioned at the “top” of physical display device 404 and the user tracking subsystem 408B positioned at the “bottom” of physical display device 404, user tracking subsystems with different numbers of components in different configurations and/or orientations will fall within the scope of the present disclosure as well.

In the illustrated embodiment, a virtual reality display subsystem (e.g., virtual reality display subsystem 410) is included with virtual reality system 400, and provides a head-mounted user tracking and display subsystem. For example, virtual reality display subsystem 410 includes a chassis (e.g., chassis 410A) that is configured to be worn on a user's head such that a display device (e.g., display device 410B) is positioned in front of the user's eyes. In the discussions below, display device 410B is provided by a transparent Organic Light Emitting Device (OLED) display device, although other display devices that provide the functionality discussed below may fall within the scope of the present disclosure as well. The virtual reality display subsystem 410 may also include a plurality of cameras (e.g., cameras 410C) that are configured to capture images in the field of view of a user wearing virtual reality display subsystem 410. In the examples discussed below, virtual reality display subsystem 410 is wirelessly coupled to computing device 402, although wired connections will fall within the scope of the present disclosure as well. While in the embodiments discussed below, much of the computing device processing for the display of images by virtual reality display subsystem 410 is performed by computing device 402 in order to provide a relatively small and lightweight virtual reality display subsystem 410, in other embodiments virtual reality display subsystem 410 may perform at least some of the computing device functionality discussed below. While not explicitly illustrated, virtual reality display subsystem 410 may include a variety of other components for use in the user tracking functionality discussed below, including IR markers (e.g., for use by IR sensors or IR sensor arrays in user tracking subsystem 408A and 408B), accelerometers, gyroscopes, locations sensors, and/or a variety of other tracking components that would be apparent to one of skill in the art in possession of the present disclosure. In experimental embodiments, virtual reality display subsystem 410 was provided by a META® headset provided by META® company of California, United States, although other virtual reality display subsystems will fall within the scope of the present disclosure as well. However, while a specific virtual reality display subsystem has been described, one of skill in the art in possession of the present disclosure will recognize that light field display devices, projection display devices, and/or other virtual reality display subsystems may be substituted for virtual reality display subsystem 410 while remaining within the scope of the present disclosure.

In the illustrated embodiment, virtual reality system 400 also includes a totem device (e.g., totem device 412) and a pen device (e.g., pen device 414), each of which may be wirelessly connected to computing device 402 (although wired connections will fall within the scope of the present disclosure as well), or capable of being tracked by virtual reality display subsystem 410 and/or user tracking subsystem 408A and 408B. Furthermore, each of totem device 412 and pen device 414 may include tracking components such as IR markers (e.g., for use by IR sensors or IR sensor arrays in user tracking subsystem 408A and 408B), cameras, accelerometers, gyroscopes, locations sensors, and/or a variety of other tracking components that would be apparent to one of skill in the art in possession of the present disclosure. While a specific virtual reality system has been described, one of skill in the art in possession of the present disclosure will recognize that virtual reality systems may include a variety of components in a variety of different configurations in order to provide for conventional virtual reality workspace functionality, as well as the functionality discussed below, while remaining within the scope of the present disclosure.

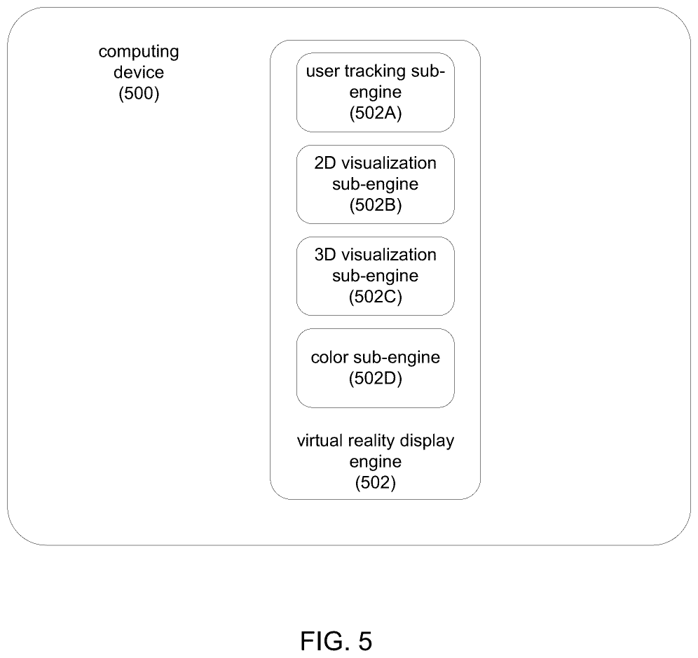

Referring also to FIG. 5, an embodiment of a computing device (e.g., computing device 500) is illustrated that may be computing device 402 discussed above with reference to FIG. 4. Furthermore, as discussed above, while a separate computing device 500 is illustrated in FIG. 5, the functionality of the computing device 500 may instead by provided by a computing system that may be at least partially distributed across the components of virtual reality system 400. In the illustrated embodiment, computing device 500 includes a processing system and a memory system that is coupled to the processing system and that includes instructions that, when executed by the processing system, cause the processing system to provide a virtual reality display engine (e.g., virtual reality display engine 502) that is configured to perform the functions of the virtual reality display engines and computing devices discussed below. However, as discussed above, rather than being provided in a separate computing device, the functionality and/or processing performed by the computing device as discussed below may instead be integrated into components of virtual reality system 400 (e.g., physical display device 404, user tracking subsystem 408A and 408B, virtual reality display subsystem 410, etc.) while remaining within the scope of the present disclosure.

In the illustrated embodiment, virtual reality display engine 502 includes a user tracking sub-engine (e.g., user tracking sub-engine 502A) that may be configured to utilize user tracking information to determine the position of the user (e.g., the user's head, the user's hands, and/or other portions of the user), a two-dimensional visualization sub-engine (e.g., two-dimensional visualization sub-engine 502B) that may be configured to generate the two-dimensional elements on display screen 404A of the physical display device 404, a three-dimensional visualization sub-engine (e.g., three-dimensional visualization sub-engine 502C) that may be configured to generate the virtual reality elements via the virtual reality display subsystem 410, and a color sub-engine (e.g., color sub-engine 502D) that may be configured to determine color details of the two-dimensional and virtual reality elements generates by two-dimensional visualization sub-engine 502B and three-dimensional visualization sub-engine 502C. However, while an example of specific sub-engines and components of virtual reality display engine 502 have been illustrated and are described in more detail below, one of skill in the art in possession of the present disclosure will recognize that virtual reality display engine 502 may include more or fewer sub-engines, and those sub-engines may be distributed across multiple different components of the virtual reality system 400 (e.g., user tracking sub-engine 502A provided in user tracking subsystem 408A and 408B, two-dimensional visualization sub-engine 502B provided in physical display device 404, the three-dimensional visualization sub-engine 502C provided in virtual reality display subsystem 410, etc.) while remaining within the scope of the present disclosure.

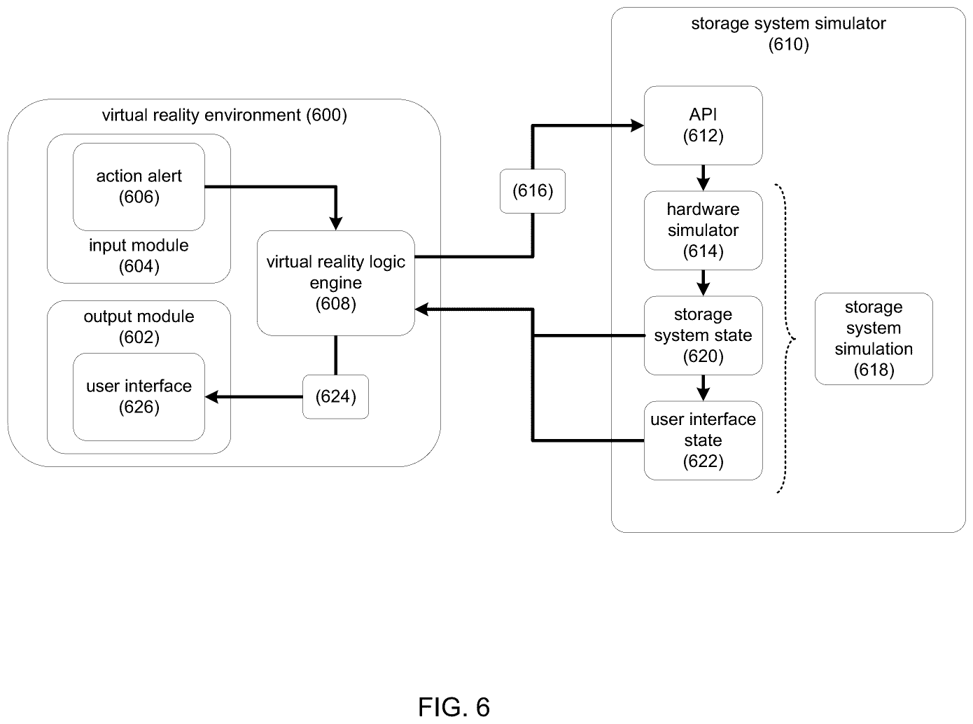

FIG. 6 depicts exemplary modules that are executed by simulation process 10 to provide a virtual reality representation of a storage system. For example, simulation process 10 may launch a virtual reality environment (e.g., virtual reality environment 600). In some implementations, simulation process 10 launches virtual environment 600 in response to a particular selection of a storage system to simulate and/or a particular training module to provide training for a particular product. The virtual reality environment 600 includes an output module 602 coupled to physical display device 404 and/or the virtual reality display subsystem 410. After retrieving data specific to the product from a data model, simulation process 10 uses at least 2D and/or 3D visualization sub-engines 502B, 502C of virtual reality display engine 304 to simulate virtual reality environment 500 in which the user can interact with a virtual reality representation of the storage system, which output module 602 sends to physical display device 204 and/or virtual reality display subsystem 410.

In some implementations, virtual reality environment 600 includes an input module (e.g., input module 604). Input module 604 is coupled to various input devices described above. For example, input module 604 may be coupled to user tracking devices 408C such as infrared (IR) sensors, IR sensor arrays (e.g., “IR castors”), or three-dimensional cameras. Additional input devices may include a totem device 412 that the user may hold, virtual reality gloves (not shown) for the user to wear, and/or a pen device 414 the user may deploy to select items on a touchscreen display. In some implementations, simulation process 10 may monitor various signals (i.e., action alerts) from virtual reality environment 600.

In some implementations, simulation process 10 provides a virtual reality representation of a storage system. For example, the virtual reality representation of the storage system and the storage system simulation may be associated with a training program for a product. For example, to train the user, a training program may be executed in connection with virtual reality environment 600 by outputting instructions to guide the user in performing various tasks on a virtual representation of a storage system and a storage system simulation. After each instruction is displayed, an event handler of input module 604 waits for the user to complete the requested action. The input module 604 interprets signals from input devices, and when the signals amount to a known action, an action alert is sent to the event handler to process. The event handler uses data from a data model to determine if the action satisfies the instruction presented to the user. As will be discussed in greater detail below, simulation process 10 may update a storage system simulation state and/or a user interface state for a user interface of the virtual reality representation of the storage system based on the action alert.

In some implementations, simulation process 10 receives 306 a selection of a storage system simulation from a plurality of storage system simulations corresponding to physical storage systems. For example, simulation process 10 may provide a user interface configured to display various configurations for storage system simulations that a user may customize. In some implementations, the storage system simulation may be predefined for a particular training exercise from a menu or listing of many storage system simulations and/or training exercises associated with multiple storage system simulations. In one example, a user may select the storage system simulation that corresponds to a physical storage system installed at a particular site. In this manner, the user may use the combination of a virtual reality representation of the storage system and the storage system simulation to practice various exercises on the storage system corresponding to the physical storage system installed at a particular site.

As will be discussed in greater detail below, based on the storage system simulation and the action alert, simulation process 10 generates a response to the user. The response is sent to the output module 602 of the virtual reality environment 600, to update the display on the physical display device 404 and/or the virtual reality display subsystem 410.

For example, if the input event is unsatisfactory, the virtual reality environment 600 may reset to the display originally accompanying the instruction. The user may be invited to reattempt the task. In some embodiments, the virtual reality environment 600 may display an explanation why the user's input was incorrect and/or inadequate, and provide more detailed guidance on how to complete the task. In another example, if the input event is satisfactory, the event handler deems the user to have been properly trained for the task, and the program advances to the next task in the training. Consequently, the event handler 610 updates the virtual reality environment 600 to display a new instruction to the user and to present the product in the state requiring a next task to be performed.

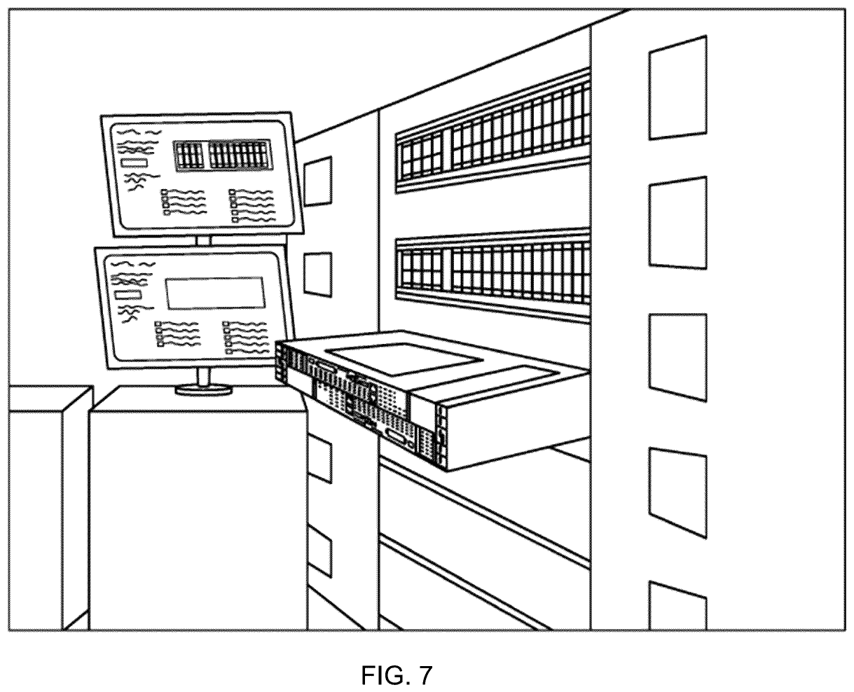

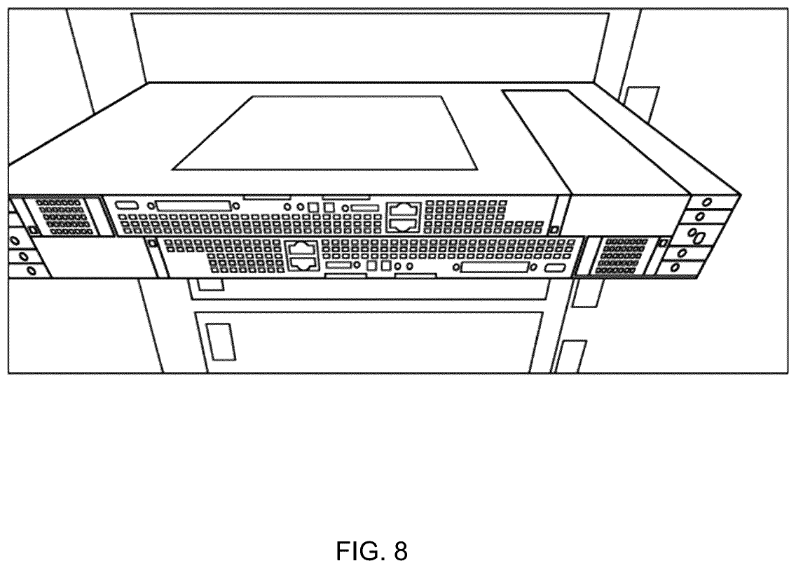

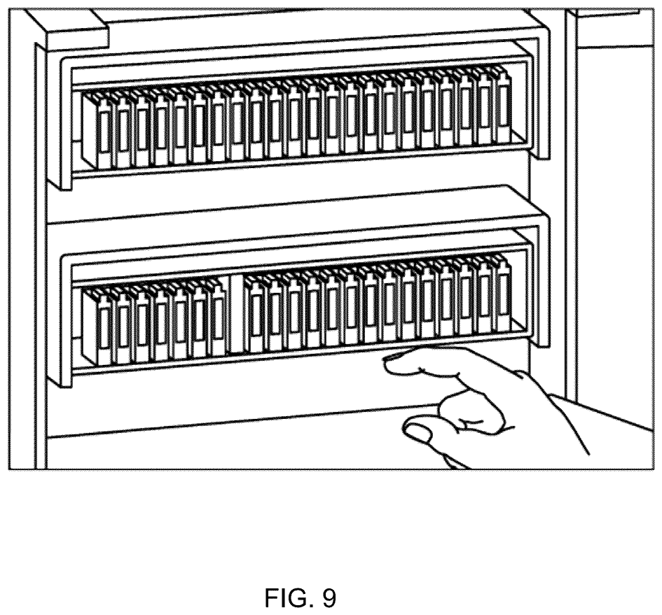

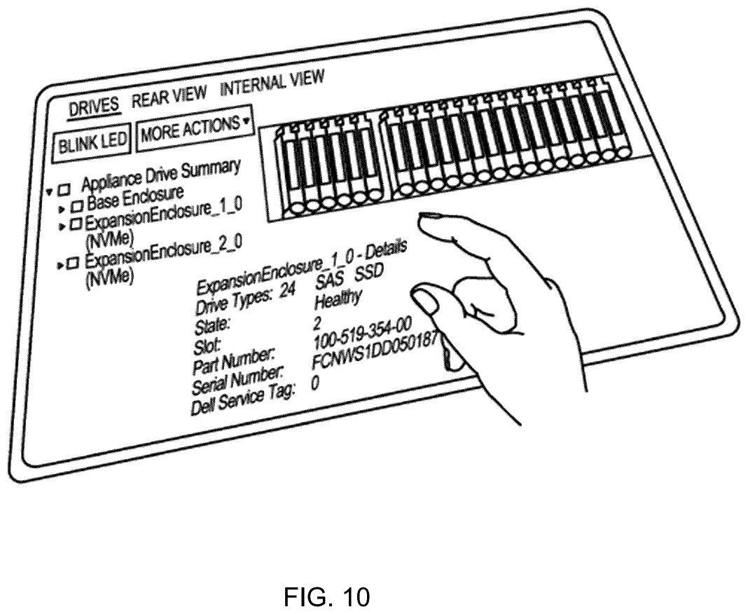

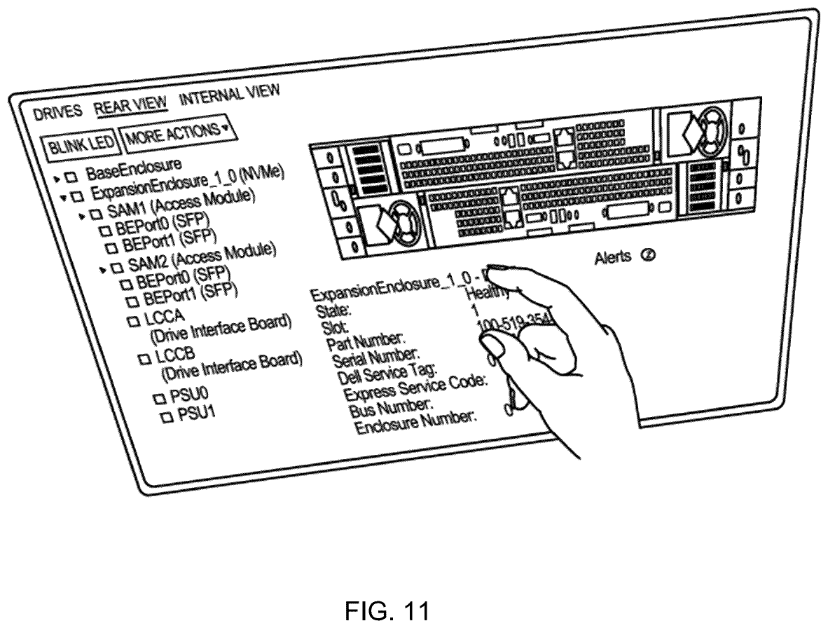

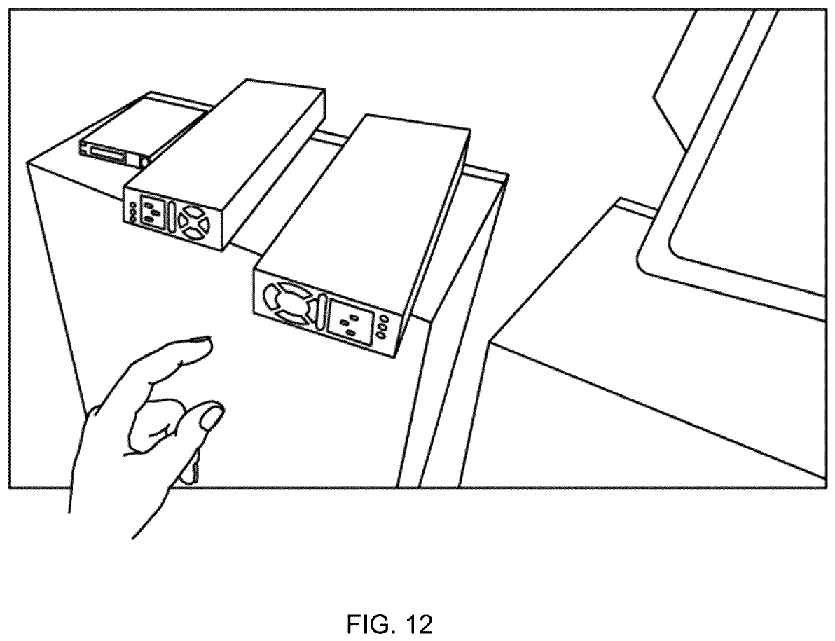

Referring also to FIGS. 7-16 which depict exemplary screenshots of a virtual reality environment 600 providing a simulation of a storage system (e.g., a virtual reality representation of a storage system). FIG. 7 depicts a virtual server room. Three expansion shelves for a product can be seen, as well as two screens with user interfaces depicting the system status. FIG. 8 depicts the bottom expansion shelf in an extended, back-facing view. Spaces a color-coded to indicate that a part is missing. FIG. 9 show the two top expansion shelves, which are forward facing so that the drives are visible. A color-coded space indicates where a drive is missing. FIG. 10 depicts one of the user interfaces displayed on a screen in the virtual reality environment 600, alerting the user that an expansion shelf is missing a drive in a particular slot. FIG. 11 depicts the other of the user interfaces, highlighting that two power supplies are missing from the bottom expansion shelf. FIG. 12 depicts a solid-state drive (SSD) drive and two power supplies lying on a platform next to the screens in the virtual reality environment 600.

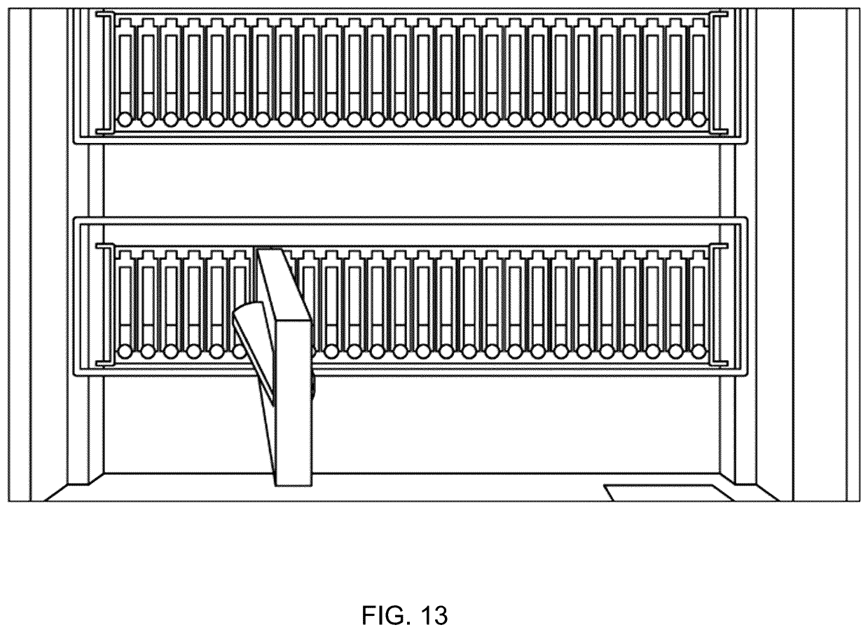

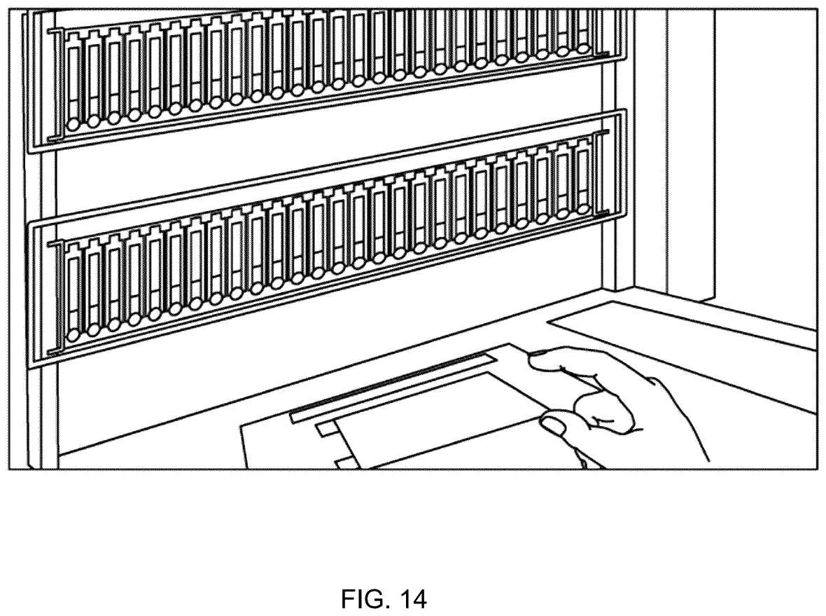

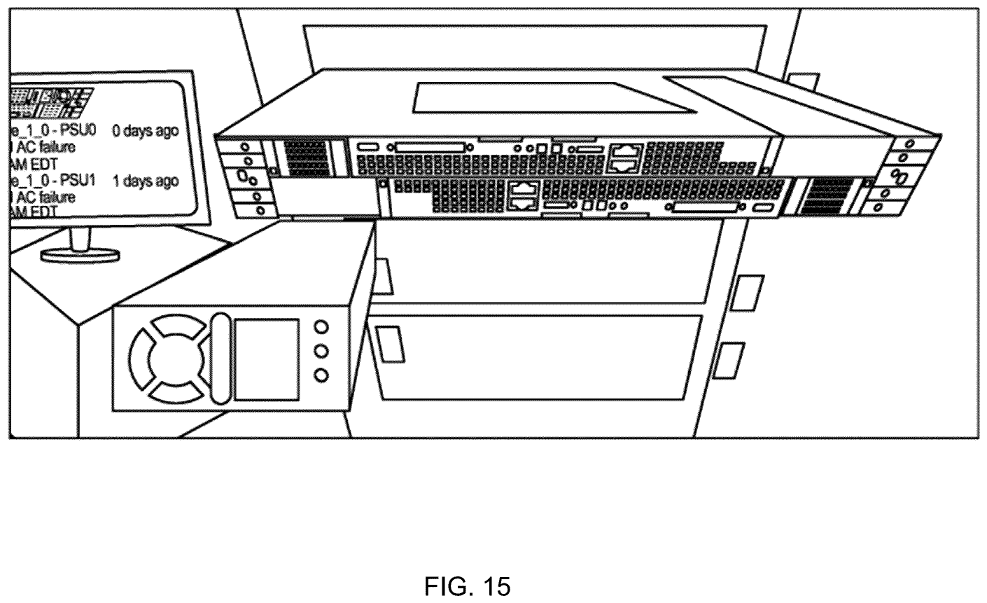

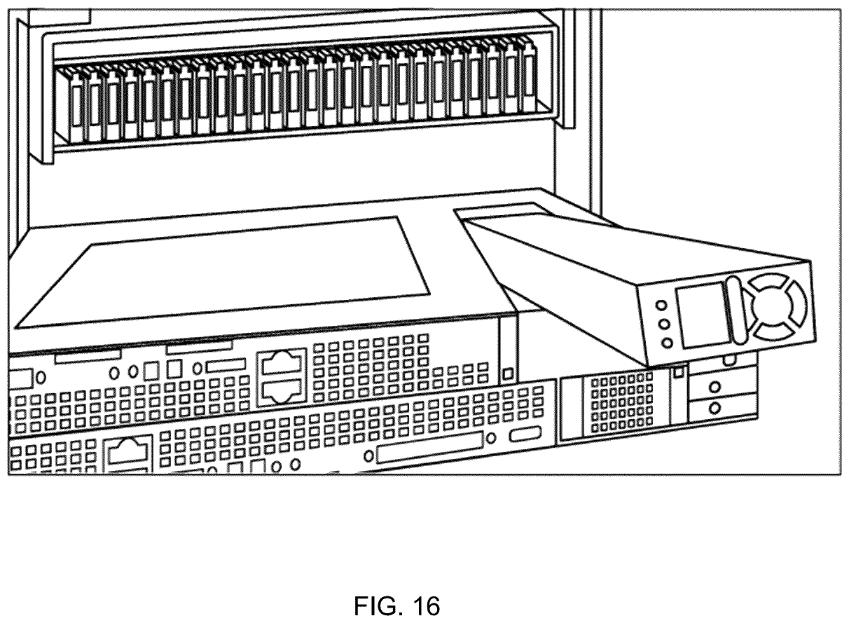

As shown in FIG. 13, the user may pick up the SSD drive in the virtual reality environment 600, and insert the SSD drive into the empty slot in the middle expansion shelf. When the SSD drive is correctly positioned, the drive snaps into place in the display, as shown in FIG. 14. Similarly, the user may pick up the power supplies and insert them into the bottom expansion shelf, as shown in FIGS. 15 and 16. If the power supplies are positioned correctly, the power supplies snap into place.

In some implementations, simulation process 10 may receive 300 an action alert from a virtual reality system concerning a virtual reality representation of a storage system. An action alert includes an alert that a particular predefined action has been detected in the virtual reality environment. For example, suppose that a user is using the virtual reality system to interface with a virtual reality representation of a storage system as shown in FIGS. 12-13, where a user inserts an SSD drive into the empty slot of the virtual reality representation of the storage system. In this example, simulation process 10 may receive an action alert (e.g., action alert 606) from a virtual reality system (e.g., virtual reality system 400) concerning the action performed by the user in virtual reality environment 600 on the virtual reality representation of the storage system (i.e., user inserting an SSD drive into the virtual reality representation of the storage system). In some implementations, simulation process 10 may provide or access a listing of actions that constitute an action alert. In one example, any interaction with a virtual representation of a storage system results in the generation of an action alert. In some implementations, simulation process 10 may receive and/or generate action alert 606 at input module 604 of virtual reality environment 600.

In some implementations, simulation process 10 translates 302 the action alert into a storage system simulator event using a virtual reality logic engine. For example and continuing with the above example, suppose that a user inserts an SSD drive into the empty slot of the virtual reality representation of the storage system. In this example, simulation process 10 receives 300 action alert 606 indicating that the user has inserted the SSD drive into an empty slot of the virtual reality representation of the storage system. Simulation process 10 may translate action alert 606 into a storage system simulator event using a virtual reality logic engine (e.g. virtual reality logic engine 608). In some implementations, virtual reality logic engine 608 is a software module that performs two primary functions: 1) translating 302 action alerts into storage system simulator events; and 2) polling a storage system simulation state and a user interface state for a user interface of the virtual reality representation of the storage system.

In some implementations, translating 302 the action alert (e.g., action alert 606) includes processing the action alert to identify the action performed on a particular portion or portions of the virtual reality representation of the storage system and mapping the action to an event associated with the storage system simulation. For example, a storage system simulator event is a signal that describes a change to a storage system simulation. In some implementations, virtual reality logic engine 608 may include a predefined mapping of various action alerts to corresponding storage system simulator events.

Referring again to FIG. 6, a storage system simulator (e.g., storage system simulator 610) is a software module configured to simulate/model the hardware and software of a storage system. For example, simulation process 10 may receive a selection of particular storage system components and configurations to define a storage system simulation. In one example, simulation process 10 receives a user selection of particular components and/or default components to include in a storage system simulation. In some implementations, simulation process 10 may include an application programming interface (API) (e.g., 612) configured to process storage system simulator events using a hardware simulator (e.g., hardware simulator 614). Hardware simulator 614 may be configured to simulate the operation of various hardware components of a storage system (e.g., hard disk drives (HDDs), SSDs, cache memory systems, power supplies, battery backup systems, network interface cards (NICs), etc.). In this manner, hardware simulator 614 includes various algorithms and models to represent each component of the storage system. Accordingly, hardware simulator 614 can represent the functionality of a storage system without requiring actual components.

In some implementations, simulation process 10 updates 304 a storage system simulation corresponding to the virtual reality representation of the storage system using the storage system simulator event. For example, suppose that simulation process 10 translates 302 action alert 606 concerning a user inserting an SSD drive into the empty slot of the virtual reality representation of the storage system into a storage system simulator event (e.g., storage system simulator event 616) using virtual reality logic engine 608. In some implementations, simulation process 10 uses storage system simulator event 616 to update 304 a storage system simulation (e.g., storage system simulation 616).

In some implementations, updating 304 the storage system simulation includes providing 308 the storage system simulator event to the storage system simulation using an application programming interface (API). As discussed above, simulation process 10 uses API 612 to provide 308 storage system simulator event 616 from virtual reality logic engine 608 to hardware simulator 614 of storage system simulator 618. In some implementations, API 612 may allow virtual reality logic engine 608 to communicate according to the communication protocols of storage system simulator 618.

In some implementations, updating 304 the storage system simulation includes updating 310 a storage system simulation state. A storage system simulation state generally includes the current condition of the various hardware and software components of the storage system simulation (e.g., storage system simulation 618). In some implementations, storage system simulator event 616 describes a change in the storage system state. For example, simulation process 10 uses hardware simulator 614 and storage system simulator event 616 to update 310 the storage system simulation state (e.g., storage system simulation state 620) associated with storage system simulation 618. In some implementations, updating 310 the storage system simulation state includes updating, modifying, adding, and/or removing simulated storage system components (e.g., adding an SSD drive, reconfiguring a RAID array, replacing a power supply unit (PSU), etc.). In this manner, the storage system simulation state includes the current condition of the various simulated components of the storage system simulation.

In some implementations, updating 304 the storage system simulation includes updating 312 a user interface state for a user interface of the virtual reality representation of the storage system. A user interface state generally includes the condition of a user interface or multiple user interfaces associated with the storage system simulation. For example, a storage system simulation (e.g., storage system simulation 618) may populate a user interface with information regarding the operation of the storage system simulation. Continuing with the above example, simulation process 10 may update 312 storage system simulation 618 to include information concerning the newly added SSD. In some implementations, simulation process 10 updates 312 a user interface state (e.g., user interface state 622) for a user interface of the virtual reality representation of the storage system.

In some implementations, simulation process 10 updates 314 the virtual reality representation of the storage system on the virtual reality system. For example, simulation process 10 may use virtual reality logic engine 608 to poll or request the updated storage system state (e.g., storage system state 620) and/or the user interface state 622 for a user interface of virtual reality representation of the storage system. In some implementations, virtual reality logic engine 608 may translate the storage system state (e.g., storage system state 620) and/or the user interface state (e.g., user interface state 622) to an update to the virtual reality representation of the storage system (e.g., virtual reality representation update 624). For example, simulation process 10 may process virtual reality representation update 624 concerning the user inserting an SSD drive in the virtual reality representation of the storage system. As shown in FIG. 6, simulation process 10 may provide virtual reality representation update 624 to output module 602 to update the display of the virtual reality environment (e.g., virtual reality environment 600).

In some implementations, updating 314 the virtual reality representation of the storage system on the virtual reality system includes updating 316 the user interface of the virtual reality representation of the storage system. For example, suppose that a virtual reality representation of the storage system includes a user interface (e.g., the user interface shown in FIG. 11). Further suppose that the user interface does not include any reference to the new SSD when the SSD is initially inserted into the empty slot of the storage system as discussed above. In this example, suppose that simulation process 10 updates 316 the storage system simulation associated with the virtual reality representation of the storage system. In some implementations, simulation process 10 updates 316 the user interface of the virtual reality representation of the storage system by updating the user interface(s) displayed within the virtual reality representation of the storage system. In one example, updating 316 the user interface(s) of the virtual reality representation of the storage system includes providing alerts, events, or other graphical indicators for display on the user interface within the virtual reality representation of the storage system. Simulation process 10 may provide virtual reality representation update 316 to output module 602 such that output module 602 updates 316 the user interface (e.g., user interface 626) of the virtual reality representation of the storage system. In this manner, simulation process 10 may update 316 the user interface shown in the virtual reality representation of the storage system to include information generated by the storage system simulation.

### GENERAL

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet (e.g., network 14).

The present disclosure is described with reference to flowchart illustrations and/or block diagrams of methods, apparatus (systems) and computer program products according to implementations of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various implementations of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various implementations with various modifications as are suited to the particular use contemplated.

A number of implementations have been described. Having thus described the disclosure of the present application in detail and by reference to implementations thereof, it will be apparent that modifications and variations are possible without departing from the scope of the disclosure defined in the appended claims.

What is claimed is:

1. A computer-implemented method, executed on a computing device, comprising:
receiving an action alert from a virtual reality system concerning a virtual reality representation of a storage system;
translating the action alert into a storage system simulator event using a virtual reality logic engine; and
updating a storage system simulation corresponding to the virtual reality representation of the storage system using the storage system simulator event.

2. The computer-implemented method of claim 1, wherein updating the storage system simulation includes providing the storage system simulator event to the storage system simulation using an application programming interface (API).

3. The computer-implemented method of claim 1, wherein updating the storage system simulation includes updating a storage system simulation state.

4. The computer-implemented method of claim 1, wherein updating the storage system simulation includes updating a user interface state for a user interface of the virtual reality representation of the storage system.

5. The computer-implemented method of claim 4, further comprising:
updating the virtual reality representation of the storage system on the virtual reality system.

6. The computer-implemented method of claim 5, wherein updating the virtual reality representation of the storage system on the virtual reality system includes updating the user interface of the virtual reality representation of the storage system.

7. The computer-implemented method of claim 1, further comprising:
receiving a selection of a storage system simulation from a plurality of storage system simulations corresponding to physical storage systems.

8. A computer program product residing on a non-transitory computer readable medium having a plurality of instructions stored thereon which, when executed by a processor, cause the processor to perform operations comprising:
receiving an action alert from a virtual reality system concerning a virtual reality representation of a storage system;
translating the action alert into a storage system simulator event using a virtual reality logic engine; and
updating a storage system simulation corresponding to the virtual reality representation of the storage system using the storage system simulator event.

9. The computer program product of claim 8, wherein updating the storage system simulation includes providing the storage system simulator event to the storage system simulation using an application programming interface (API).

10. The computer program product of claim 8, wherein updating the storage system simulation includes updating a storage system simulation state.

11. The computer program product of claim 8, wherein updating the storage system simulation includes updating a user interface state for a user interface of the virtual reality representation of the storage system.

12. The computer program product of claim 11, wherein the operations further comprise:
updating the virtual reality representation of the storage system on the virtual reality system.

13. The computer program product of claim 12, wherein updating the virtual reality representation of the storage system on the virtual reality system includes updating the user interface of the virtual reality representation of the storage system.

14. The computer program product of claim 8, wherein a storage system simulator and the virtual reality system are configured to be upgraded independently.

15. A computing system comprising:
a memory; and
a processor configured to receiving an action alert from a virtual reality system concerning a virtual reality representation of a storage system, to translate the action alert into a storage system simulator event using a virtual reality logic engine, and to update a storage system simulation corresponding to the virtual reality representation of the storage system using the storage system simulator event.

16. The computing system of claim 15, wherein updating the storage system simulation includes providing the storage system simulator event to the storage system simulation using an application programming interface (API).

17. The computing system of claim 15, wherein updating the storage system simulation includes updating a storage system simulation state.

18. The computing system of claim 15, wherein updating the storage system simulation includes updating a user interface state for a user interface of the virtual reality representation of the storage system.

19. The computing system of claim 18, wherein the processor is further configured to:
update the virtual reality representation of the storage system on the virtual reality system.

20. The computing system of claim 19, wherein updating the virtual reality representation of the storage system on the virtual reality system includes updating the user interface of the virtual reality representation of the storage system.
